(19) United States
(12) Patent Application Publication
(10) Pub. No.: US 2013/0240834 A1
(43) Pub. Date: Sep. 19, 2013

(54) METHOD FOR FABRICATING VERTICAL LIGHT EMITTING DIODE (VLED) DICE WITH WAVELENGTH CONVERSION LAYERS

(71) Applicant: SemiLEDS Optoelectronics Co., Ltd., Chu-Nan 350 (TW)

(72) Inventors: CHUONG ANH TRAN, Hsinchu County 308 (TW); Trung T. Doan, Hsinchu County 308 (TW); David Trung Doan, Hsinchu County 308 (TW)

(73) Assignee: SemiLEDS Optoelectronics Co., Ltd., Chu-Nan 350 (TW)

(21) Appl. No.: 13/893,401

(22) Filed: May 14, 2013

Related U.S. Application Data
(63) Continuation-in-part of application No. 13/227,335, filed on Sep. 7, 2011.
Application No. 13/227,335 is a continuation-in-part of application No. 13/191,235, filed on Jul. 26, 2011.
Application No. 13/191,235 is a continuation-in-part of application No. 11/530,128, filed on Sep. 8, 2006, now Pat. No. 8,012,774.
Application No. 11/530,128 is a continuation-in-part of application No. 11/032,853, filed on Jan. 11, 2005, now Pat. No. 7,195,944.

(51) Int. Cl. H01L 33/50

(52) U.S. Cl. CPC H01L 33/505
USPC 257/13; 438/29

(57) ABSTRACT

A method for fabricating vertical light emitting diode (VLED) dice includes the steps of: forming a light emitting diode (LED) die having a multiple quantum well (MQW) layer configured to emit electromagnetic radiation in a first spectral region; forming a confinement layer on the multiple quantum well (MQW) layer; forming an adhesive layer on the confinement layer; and forming a wavelength conversion layer on the adhesive layer configured to convert the electromagnetic radiation in the first spectral region to output electromagnetic radiation in a second spectral region.

### CROSS-REFERENCE TO RELATED APPLICATIONS

This application is a continuation-in-part of Ser. No. 13/227,335, filed Sep. 7, 2011; which is a continuation-in-part of Ser. No. 13/191,235, filed Jul. 26, 2011; which is a continuation-in-part of Ser. No. 11/530,128, filed Sep. 8, 2006, U.S. Pat. No. 8,012,774; which is a continuation-in-part of Ser. No. 11/032,853, filed Jan. 11, 2005, U.S. Pat. No. 7,195,944; all of which are incorporated by reference.

### BACKGROUND

This disclosure relates generally to light emitting diode (LED) dice having wavelength conversion layers and to methods for fabricating vertical light emitting diode (VLED) dice with wavelength conversion layers.

Light emitting diode (LED) dice have been developed that produce white light. In order to produce white light, a blue (LED) die can be used in combination with a wavelength conversion layer, such as a phosphor layer formed on the surface of the (LED) die. The electromagnetic radiation emitted by the blue (LED) die excites the atoms of the wavelength conversion layer, which converts some of the electromagnetic radiation in the blue wavelength spectral region to the yellow wavelength spectral region. The ratio of the blue to the yellow can be manipulated by the composition and geometry of the wavelength conversion layer, such that the output of the light emitting diode (LED) die appears to be white light.

The present disclosure is directed to a method for fabricating vertical light emitting diode (VLED) dice configured to produce white light and to a vertical light emitting diode (VLED) die fabricated using the method.

### SUMMARY

A method for fabricating vertical light emitting diode (VLED) dice includes the steps of: forming a light emitting diode (LED) die having a multiple quantum well (MQW) layer configured to emit electromagnetic radiation in a first spectral region; forming a confinement layer on the multiple quantum well (MQW) layer; forming an adhesive layer on the confinement layer; and forming a wavelength conversion layer on the adhesive layer configured to convert the electromagnetic radiation in the first spectral region to output electromagnetic radiation in a second spectral region.

A vertical light emitting diode (VLED) die fabricated using the method includes a multiple quantum well (MQW) layer configured to emit electromagnetic radiation in a first spectral region and a confinement layer on the multiple quantum well (MQW) layer. The (VLED) die also includes an adhesive layer on the confinement layer, and a wavelength conversion layer on the adhesive layer configured to convert the electromagnetic radiation in the first spectral region to output electromagnetic radiation in a second spectral region.

### BRIEF DESCRIPTION OF THE DRAWINGS

Exemplary embodiments are illustrated in the referenced figures of the drawings. It is intended that the embodiments and the figures disclosed herein are to be considered illustrative rather than limiting.

FIG. 1 illustrates a plurality of vertical light emitting diode dice (VLED) on a wafer during a wafer level fabrication method;

FIG. 2 illustrates the formation of a phosphor layer on the vertical light emitting diode dice (VLED) during the fabrication method;

FIG. 3 illustrates patterning of the phosphor layer using a photoresist masking layer;

FIG. 4 illustrates formation of a metal contact layer on the patterned phosphor layer;

FIG. 5 illustrates formation of bond pads using the metal contact layer;

FIG. 6 illustrates a plurality of vertical light emitting diode dice (VLED) following singulation of the wafer; and

FIGS. 7A-7C are schematic cross sectional views illustrating steps in a method for fabricating an alternate embodiment vertical light emitting diode die (VLED).

### DETAILED DESCRIPTION

It is to be understood that when an element is stated as being “on” another element, it can be directly on the other element or intervening elements can also be present. However, the term “directly” means there are no intervening elements. In addition, although the terms “first”, “second” and “third” are used to describe various elements, these elements should not be limited by the term. Also, unless otherwise defined, all terms are intended to have the same meaning as commonly understood by one of ordinary skill in the art.

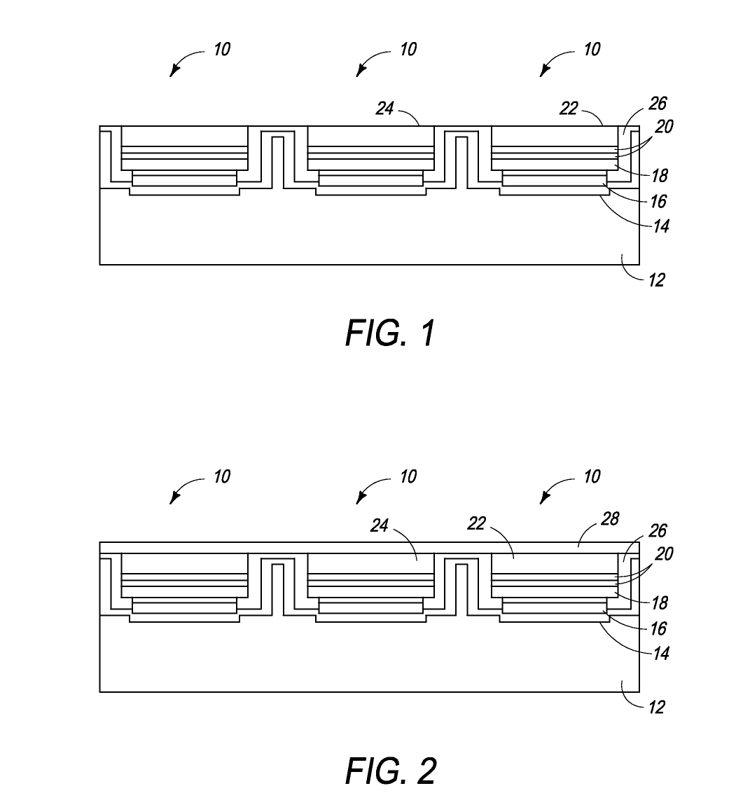

Referring to FIG. 1, initially a plurality of vertical light emitting diode (VLED) dice 10 can be provided on a LED wafer. Each vertical light emitting diode (VLED) die 10 includes a metal substrate 12, which can be made using a suitable process such as a laser lift-off process. In addition, a p-electrode 14 can be formed on the metal substrate 12. Further, a p-contact 16 and a p-GaN layer 18 can be formed on the p-electrode 14. An active region 20 (including a multi-quantum (MQW) can also be formed, and an n-GaN layer 22 can also be formed on the active region 20. The n-GaN layer 22 has an exposed surface 24.

The vertical light emitting diode (VLED) dice 10 can be formed using techniques that are known in the art. For example, the vertical light emitting diode (VLED) dice 10 can be formed by depositing a multilayer epitaxial structure above a carrier substrate such as sapphire; depositing at least one metal layer above the multilayer epitaxial structure to form the metal substrate 12; and removing the carrier substrate leaving the metal substrate 12. The metal layers can be deposited using electro chemical deposition, electroless chemical deposition, chemical vapor deposition (CVD), metal organic CVD (MOCVD), plasma enhanced CVD (PECVD), atomic layer deposition (ALD), physical vapor deposition (PVD), evaporation, or plasma spray, or any combination of these techniques. In addition, the metal substrate 12 can comprise a single or multi-layered structure, and can comprise any of various suitable metals, such as at least one of silver (Ag), aluminum (Al), titanium tungsten (TiW) tungsten (W), molybdenum (Mo), tantalum (Ta), tantalum nitride (TaN), or alloys thereof. In one embodiment, Ag/Pt or Ag/Pd or Ag.Cr can be used as a mirror layer. Nickel (Ni) can be used as a barrier for gold (Au) and as a seed layer for copper (Cu) plating, which is used as the bulk substrate. A mirror layer (comprising Ag, Al, Pt, Ti, or Cr, for example) can be deposited, and then a barrier layer comprising any of various suitable materials (such as TiN, TaN, TiWN with oxygen) can be formed above the mirror layer before the electro or electroless chemical deposition of a metal, such as Ni or Cu. For electrochemical deposition of copper, a seed layer can be deposited using CVD, OCD, PVD, ALD, or evaporation process; exemplary seed materials for copper are tungsten (W), Au, Cu, or Ni, among others.

The sapphire substrate can be removed using a laser lift-off (LLO) technique. The multilayer epitaxial structure can have a reflective metal layer coupled to the metal plating layer. A passivation layer 26 can also be formed on the sidewalls of the vertical light emitting diode (VLED) dice 10.

FIG. 2 illustrates the formation of a wavelength conversion layer in the form of a phosphor layer 28 on the vertical light emitting diode (VLED) dice 10. Since the LED wafer is substantially smooth and planar, the phosphor layer 28 can be substantially uniform and parallel to the emitting LED surface 24. Therefore, color rings on the field patterns of the vertical light emitting diode (VLED) dice 10 are minimized because the blue light emitted from the active layers travels the same distance or light path through the phosphor layer 28.

The phosphor layer 28 can be formed using a spin coater. The phosphor layer 28 can be coated by the spin-coater spinning between 500 to 3000 rpm to control the layer thickness on the n-side-up LED wafer. In addition to the spin coat method, other methods such as screen printing, roller method, or dipping method can be used to form the phosphor layer 28. After the phosphor layer 28 is deposited on the substrate, the spin coated film can be dried. The drying method is not limited as long as moisture contained in the film is evaporated. Thus, various methods including using a heater, dried air, or surface treatment such as a radiant heat lamp can be used. Alternatively, the spin coated film can be dried by leaving it in a room temperature environment for an extended period of time.

To make the material for the phosphor layer 28, a phosphor powder composition can be prepared. For example, a dispersing agent can be dispersed in purified water. The dispersion can then be stirred with a mixer and placed in the purified water in which the dispersing agent has been dispersed, and the mixture can be stirred. In the phosphor powder composition, water can be used as a dispersing medium. The phosphor powder composition can contain alcohol as a dispersing agent (or a retaining agent) and ammonium bi-chromate can be used as a photosensitive polymer. The phosphor powders can also be surface-treated during the manufacturing process, to improve the dispersion and adhesion properties thereof. The phosphor coating material can comprise phosphor elements mixed in organic chemicals such as alcohol, aerosol, binder material or resin epoxy to tune the viscosity of the coating material. The thickness can be tuned by the material viscosity and spin rate reproducibly to change the resulting CIE coordination of the white light LEDs.

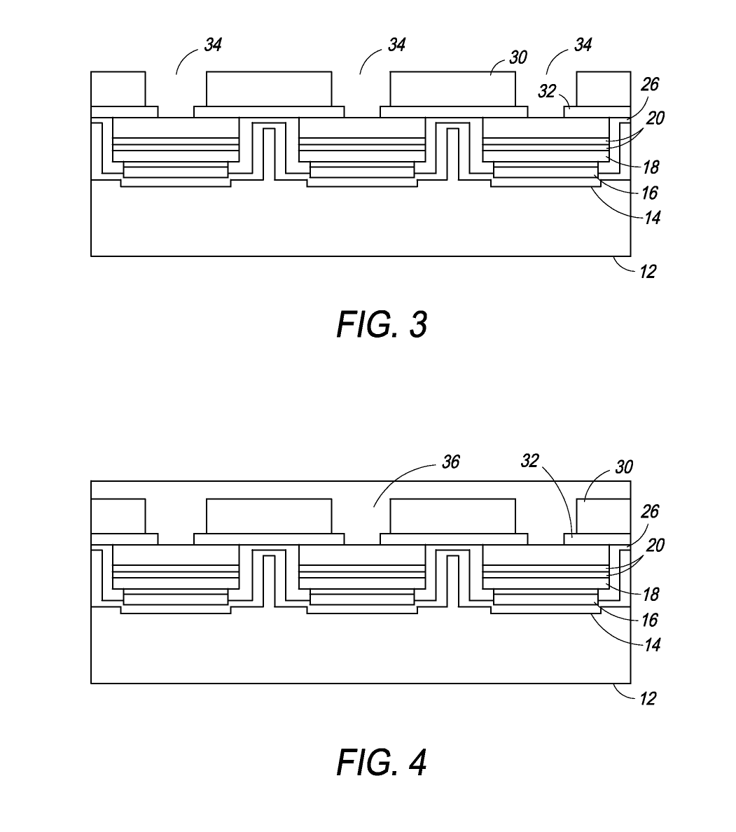

Referring to FIG. 3, a photoresist layer 30 can be applied and exposed with a contact pattern, and the phosphor layer 28 can be etched to form a patterned phosphor layer 28. The patterned phosphor layer 32 can be formed on the exposed n-GaN surface 24 and patterned using a dry etching process. The result of the etching is a plurality of openings 34 configured as contact openings for later depositing a contact metal layer 36 such as Ni/Cr.

Referring to FIG. 4, the contact metal layer 36 can comprise a metal such as Ni/Cr (Ni is in contact with n-GaN) deposited on the photoresist layer 30, in contact with the n-GaN layer 22. The contact metal layer 36 can be deposited using a suitable process such as CVD, PVD, or ebeam evaporation.

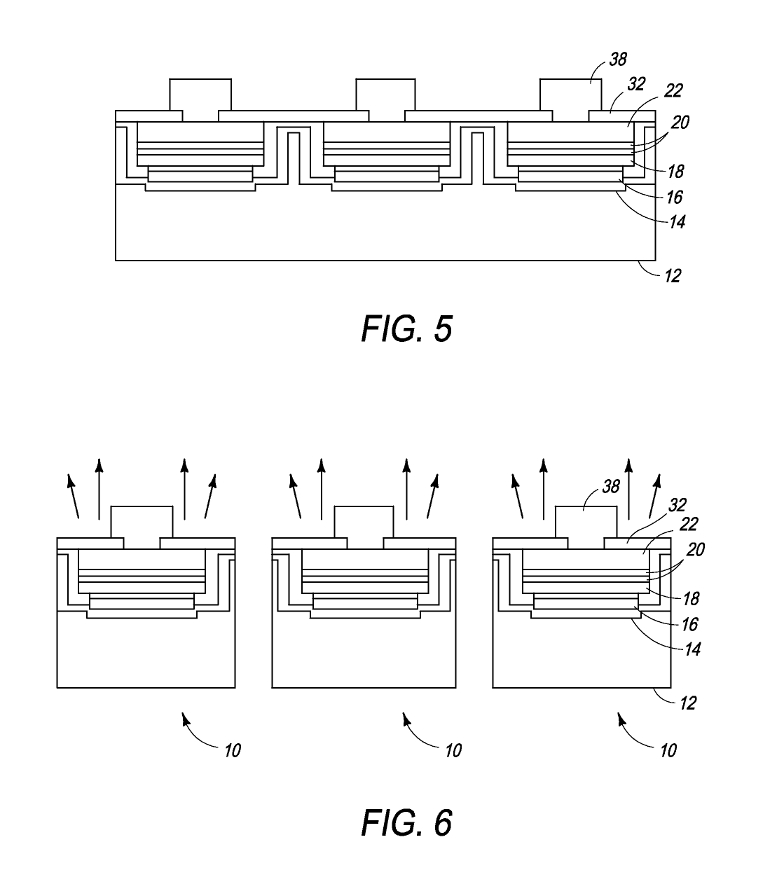

Referring to FIG. 5, bond pads 38 can be formed on the patterned phosphor layer 32 in contact with the n-GaN layer 22. The bond pads 38 can be formed by lift-off techniques during the removal of the photoresist layer 30 using an aqueous solution such as diluted KOH. The processes for phosphor coating and bonding pad formation can be performed in a different order. For example, the contact metal layer 36 can be patterned, dry etched and protected first by the photoresist layer 30 before the phosphor layer 28 is applied and patterned by lift-off technique.

Referring to FIG. 6, the LED wafer can be diced into a plurality of vertical light emitting diode (VLED) dice 10 using a suitable process. As indicated by the arrows in FIG. 6, the dice 10 are configured to emit white light. Although a single phosphor layer 28 is described above, multiple phosphor layers can also be used. For example, a red photosensitive phosphor powder composition (phosphor slurry) can be applied, exposed to light and developed. Then, a green photosensitive phosphor powder composition (phosphor slurry) can be applied, exposed to light and developed, and then a blue photosensitive phosphor powder composition (phosphor slurry) can be applied, exposed to light and developed.

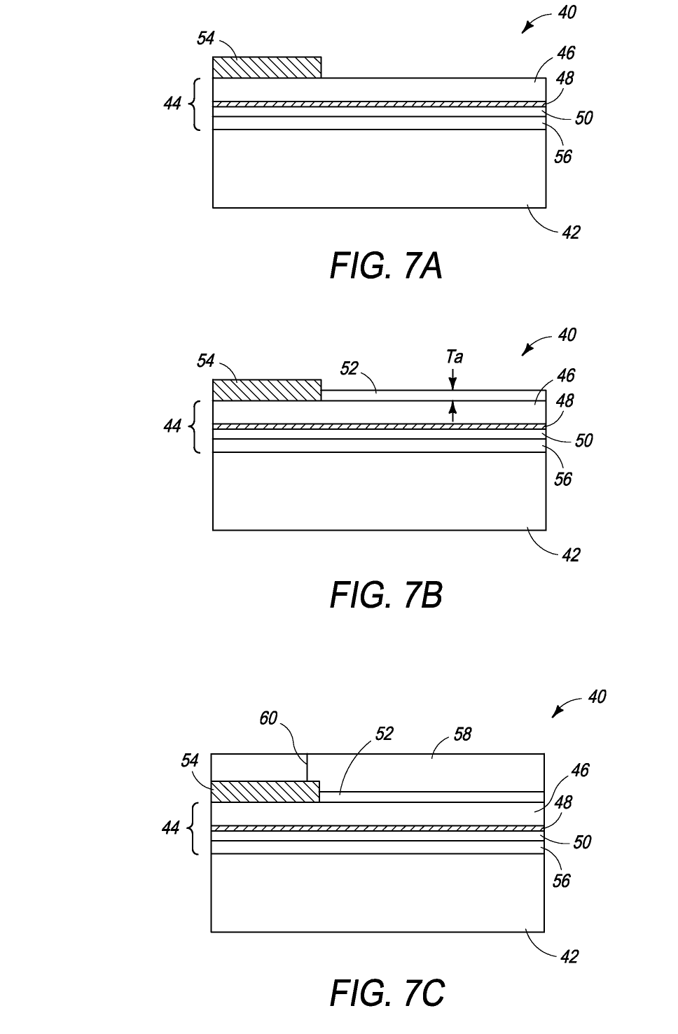

Referring to FIGS. 7A-7C, steps in a method for fabricating an alternate embodiment vertical light emitting diode (VLED) die 40 are illustrated. For simplicity, various elements of the vertical light emitting diode (LED) die 40 are not illustrated. However, this type of vertical light emitting diode (VLED) die is further described in U.S. Pat. Nos. 7,195,944 and 7,615,789, both of which are incorporated herein by reference. Although the vertical light emitting diode (VLED) die 40 is described, it is to be understood that the concepts described herein can also be applied to other types of light emitting diode (LED) dice, such as ones with planar electrode configurations. In addition, although the method is shown being performed on a single die, it is to be understood that the method can be performed at the wafer level on a wafer containing multiple dice, which can be singulated into individual dice following the fabrication process.

Initially, as shown in FIG. 7A, the method includes the step of forming (or alternately providing) the vertical light emitting diode (VLED) die 40 with a conductive substrate 42, and an epitaxial stack 44 on the conductive substrate 42. The epitaxial stack 44 includes an n-type confinement layer 46, a multiple quantum well (MQW) layer 48 in electrical contact with the n-type confinement layer 46 configured to emit electromagnetic radiation, and a p-type confinement layer 50 in electrical contact with the multiple quantum well (MQW) layer 48.

The n-type confinement layer 46 preferably comprises n-GaN. Other suitable materials for the n-type confinement layer 46 include n-AlGaN, n-InGaN, n-AlInGaN, AlInN and n-AlN. The multiple quantum well (MQW) layer 48 preferably includes one or more quantum wells comprising one or more layers of InGaN/GaN, AlGaInN, AlGaN, AlInN and AlN. The multiple quantum well (MQW) layer 48 can be configured to emit electromagnetic radiation from the visible spectral region (e.g., 400-770 nm), the violet-indigo spectral region (e.g., 400-450 nm), the blue spectral region (e.g., 450-490 nm), the green spectral region (e.g., 490-560 nm), the yellow spectral region (e.g., 560-590 nm), the orange spectral region (e.g., 590-635 nm) or the red spectral region (e.g., 635-700 nm). The p-type confinement layer 50 preferably comprises p-GaN. Other suitable materials for the p-type confinement layer 50 include p-AlGaN, p-InGaN, p-AlInGaN, p-AlInN and p-AlN.

Still referring to FIG. 7A, the vertical light emitting diode (VLED) die 10 also includes an n-bond pad 54 on the n-type confinement layer 46 and a reflector layer 56 on the conductive substrate 42. The n-bond pad 54 can have a size, peripheral shape and location suitable for wire bonding. In addition, the n-bond pad 54 can comprise a conductive wire bondable material, such as a single layer of a metal such as Al, Ti, Ni, Au, Pt, Ag or Cr, or a metal stack such as Ti/Al/Ni/Au, Al/Ni/Au, Ti/Al/Pt/Au or Al/Pt/Au. The reflector layer 56 can comprise a single layer of a highly reflective material such as Ag, Si or Al, or multiple layers, such as Ni/Ag/Ni/Au, Ag/Ni/Au, Ti/Ag/Ni/Au, Ag/Pt, Ag/Pd or Ag/Cr. All of the elements of the vertical light emitting diode (VLED) die 40 described so far can be fabricated using techniques that are known in the art.

Next, as shown in FIG. 7B, the method includes the step of forming an adhesive layer 52 on the n-type confinement layer 46 leaving the n-bond pad 54 exposed. The adhesive layer 52 can comprise a suitable adhesive formed using a suitable process such as dispensing, screen-printing, spin coating, nozzle deposition, spraying and applying a pressure sensitive adhesive (PSA). Suitable adhesives include silicone, epoxy and acrylic glue. A thickness Ta of the adhesive layer 52 can be selected as required with from 200 Å to 50 μm being representative.

Next, as shown in FIG. 7C, the method includes the step of forming a wavelength conversion layer 58 on the adhesive layer 52. The wavelength conversion layer 58 can comprise a layer of phosphor formed using a spin coater substantially as previously described. Other suitable processes for forming the wavelength conversion layer 58 include lithography, dip-coating, dispensing using a material dispensing system, printing, jetting, spraying, chemical vapor deposition (CVD), thermal evaporation and e-beam evaporation. The wavelength conversion layer 58 can also include an opening 60 aligned with the n-bond pad 54 for providing access to the n-bond pad 54. The opening 60 can be formed by etching the wavelength conversion layer 58 using a photomask substantially as previously described.

The wavelength conversion layer 58 can have a peripheral shape that substantially matches the peripheral shape of the vertical light emitting diode (VLED) die 40. The wavelength conversion layer 58 is configured to convert at least some of the electromagnetic radiation emitted by the multiple quantum well (MQW) layer 48 into electromagnetic radiation having a different wavelength range, such as a higher wavelength range. For example, if the multiple quantum well (MQW) layer 48 emits electromagnetic radiation in a blue spectral range, the wavelength conversion layer 58 can be configured to convert at least some of this radiation to a yellow spectral range, such that the output of the vertical light emitting diode (VLED) die 40 appears to be white light.

While a number of exemplary aspects and embodiments have been discussed above, those of skill in the art will recognize certain modifications, permutations, additions and subcombinations thereof. It is therefore intended that the following appended claims and claims hereafter introduced are interpreted to include all such modifications, permutations, additions and sub-combinations as are within their true spirit and scope.

We claim:

1. A method for fabricating a vertical light-emitting diode (LED) die comprising:
forming a light emitting diode (LED) die having a multiple quantum well (MQW) layer configured to emit electromagnetic radiation in a first spectral region;
forming a confinement layer on the multiple quantum well (MQW) layer;
forming an adhesive layer on the confinement layer; and
forming a wavelength conversion layer on the adhesive layer configured to convert the electromagnetic radiation in the first spectral region to output electromagnetic radiation in a second spectral region.

2. The method of claim 1 wherein the forming the wavelength conversion layer step comprises spin-coating, lithography, dip-coating, dispensing using a material dispensing system, printing, jetting, spraying, chemical vapor deposition (CVD), thermal evaporation and e-beam evaporation.

3. The method of claim 1 wherein the forming the adhesive layer step comprises dispensing, screen-printing, spin coating, nozzle deposition, spraying or applying a pressure sensitive adhesive (PSA).

4. The method of claim 1 wherein the adhesive layer comprises a material selected from the group consisting of silicone, epoxy and acrylic glue.

5. The method of claim 1 wherein the first spectral region comprises a blue spectral region and the second spectral region comprises a yellow spectral region.

6. The method of claim 1 wherein the confinement layer comprises an n-type confinement layer.

7. The method of claim 1 wherein the wavelength conversion layer comprises a phosphor.

8. A method for fabricating light emitting diode (LED) dice comprising:
forming or providing a vertical light emitting diode (VLED) die comprising an n-type confinement layer having an n-type wire bond pad, a multiple quantum well (MQW) layer configured to emit electromagnetic radiation in a first spectral region, and a p-type confinement layer;
forming an adhesive layer on the confinement layer and leaving the wire bond pad at least partially exposed;
forming a wavelength conversion layer on the adhesive layer comprising a wavelength conversion material configured to convert the electromagnetic radiation in the first spectral region to output electromagnetic radiation in a second spectral region; and
placing the wavelength conversion member on the adhesive layer.

9. The method of claim 8 wherein the forming the wavelength conversion layer step comprises spin coating.

10. The method of claim 8 wherein the forming the adhesive layer step comprises dispensing, screen-printing, spin coating, nozzle deposition, spraying or applying a pressure sensitive adhesive (PSA).

11. The method of claim 8 wherein the adhesive layer comprises a material selected from the group consisting of silicone, epoxy and acrylic glue.

12. The method of claim 8 wherein the first spectral region comprises a blue spectral region and the second spectral region comprises a yellow spectral region.

13. The method of claim 8 wherein the wavelength conversion layer comprises a phosphor.

14. A vertical light emitting diode (VLED) die comprising:
a multiple quantum well (MQW) layer configured to emit electromagnetic radiation in a first spectral region;
a confinement layer on the multiple quantum well (MQW) layer;
an adhesive layer on the confinement layer; and
a wavelength conversion layer on the adhesive layer configured to convert the electromagnetic radiation in the first spectral region to output electromagnetic radiation in a second spectral region.

15. The vertical light emitting diode (VLED) die of claim 14 wherein the adhesive layer comprises a material selected from the group consisting of silicone, epoxy and acrylic glue.

16. The vertical light emitting diode (VLED) die of claim 14 wherein the first spectral region comprises a blue spectral region and the second spectral region comprises a yellow spectral region.

17. The vertical light emitting diode (VLED) die of claim 14 wherein the wavelength conversion layer comprises a phosphor.

18. The vertical light emitting diode (VLED) die of claim 14 wherein the confinement layer comprises an n-type confinement layer.
